(19) United States
(12) Patent Application Publication
(10) Pub. No.: US 2005/0041395 A1
(43) Pub. Date: Feb. 24, 2005

(54) Multifunctional dispersants

(75) Inventors: Craig D. Tipton, Perry, OH (US); Shreyasi Lahiri, Mentor, OH (US); Mark R. Baker, Lyndhurst, OH (US)

Correspondence Address: THE LUBRIZOL CORPORATION;ATTN: DOCKET CLERK, PATENT DEPT., 29400 LAKELAND BLVD., WICKLIFFE, OH, 44092, US

(73) Assignee: The Lubrizol Corporation, Wickliffe, OH (US)

(21) Appl. No.: 10/645,373

(22) Filed: Aug. 21, 2003

(51) Int. Cl. H05K 7/20

(52) U.S. Cl. 361/715

(57) ABSTRACT

A multifunctional dispersant useful in lubricating compositions is prepared by heating together (a) a dispersant and (b) 2,5-dimercapto-1,3,4-thiadiazole or a hydrocarbyl-substituted 2,5-dimercapto-1,3,4-thiadiazole which is substantially insoluble in a hydrocarbon oil of lubricating viscosity at 25° C., and further either (c) a borating agent or (d) an inorganic phosphorus compound, or both (c) and (d). The heating is sufficient to provide a reaction product of (a), (b), and (c) or (d) which is soluble in hydrocarbon oil at 25° C.

### BACKGROUND OF THE INVENTION

The present invention relates to a lubricant additive formulation containing a multifunctional dispersant, and its use in lubricants, particularly in automatic transmission fluids.

Automatic transmission fluids (ATFs) present highly challenging technological problems and solutions for satisfying the multiple and often conflicting lubricating and power transmitting requirements of modern automatic transmissions (including continuously variable transmissions of various types). Many additive components are typically included in an ATF, providing such performance characteristics as lubrication, dispersancy, friction control (for clutches), antiwear performance, and anti-corrosion and anti-oxidation performance. Finding and providing the correctly balanced composition is a significant formulating challenge.

Examples of formulations that have been employed in the past include those represented by U.S. Pat. No. 5,164,103, Papay, Nov. 17, 1992, which discloses preconditioned ATFs made by using a preblend formed by heating an alkenyl succinimide or succinimide detergent with a phosphorus ester and water to partially hydrolyze the ester, and then mixing the preblend and other additives with a base oil. Boronating agents can also be used. Thiadiazole derivatives can be included as another additive.

U.S. Pat. No. 5,344,579, Ohtani et al, Sep. 6, 1994, discloses a friction modifier composition which can be used in a wet clutch or wet brake system. The composition comprises a hydroxyalkyl aliphatic imidazoline and a di(hydroxyalkyl)aliphatic tertiary amine. The compositions can also contain a phosphorus-containing ashless dispersant and/or a boron-containing ashless dispersant. Among other components are copper corrosion inhibitors such as 2,5-dimercapto-3,4,-thiadiazole.

U.S. Pat. No. 6,251,840, Ward, Jr. et al., Jun. 26, 2001, discloses an automatic transmission fluid comprising a majority of an oil having a certain viscosity, 0.025-5 weight percent 2,5-dimercapto-1,3,4-thiadiazole (DMTD) or one or more derivatives of DMTD; an antifoam agent; and 0.01-0.3 weight percent of 85% phosphoric acid. Derivatives of DMTD include products from combining an oil soluble dispersant with DMTD. These can be obtained by mixing a thiadiazole, preferably DMTD with an oil-soluble carboxylic dispersant in a diluent by heating the mixture above about 100° C.

In another area (internal combustion engine lubrication), U.S. Pat. No. 4,136,043, Davis, Jan. 23, 1979, discloses compositions which form homogeneous blends with lubricating oils and the like, produced by preparing a mixture of an oil-soluble dispersant and a dimercaptothiadiazole and heating the mixture above about 100° C. The compositions are useful for suppression of copper activity and “lead paint” deposition in lubricants.

The present invention solves the problem of providing a lubricant additive, especially for an ATF, which provides multiple aspects of the required functionality to the lubricant, by way of supplying a multifunctional dispersant, thus reducing the complexity and variability, and potentially also the treat rate and cost, of the formulation.

### SUMMARY OF THE INVENTION

The present invention provides a composition comprising the product prepared by heating together: (a) a dispersant and (b) 2,5-dimercapto-1,3,4-thiadiazole or a hydrocarbyl-substituted 2,5-dimercapto-1,3,4-thiadiazole which is substantially insoluble in a hydrocarbon oil of lubricating viscosity at 25° C., and further either (c) a borating agent or (d) an inorganic phosphorus compound, or both (c) and (d), said heating being sufficient to provide a reaction product of (a), (b), and (c) or (d) which is soluble in said hydrocarbon oil at 25° C.

The invention further provides a composition comprising an oil of lubricating viscosity and the composition described above, as well as a method for lubricating a mechanical device such as a transmission, comprising supplying thereto said lubricant composition.

### DETAILED DESCRIPTION OF THE INVENTION

Various preferred features and embodiments will be described below by way of non-limiting illustration.

(a) The dispersant. The first component of the present invention is a dispersant. Dispersants are well known and include succinimide dispersants, Mannich dispersants, ester-containing dispersants, condensation products of a fatty hydrocarbyl monocarboxylic acylating agents with an amine or ammonia, alkyl amino phenol dispersants, hydrocarbyl-amine dispersants, polyether dispersants, polyetheramine dispersants, and viscosity modifiers containing dispersant functionality.

Succinimide dispersants are N-substituted long chain alkenyl succinimides, having a variety of chemical structures including typically 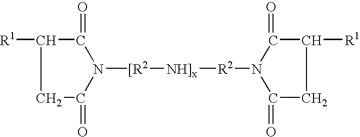
where each R¹ is independently a hydrocarbyl or alkyl group (which may be substituted by more than one succinimide group), frequently a polyisobutyl group with a molecular weight of 500-5000, and R² are alkylene groups, commonly ethylene (C₂H₄) groups. Such molecules are commonly derived from reaction of an alkenyl acylating agent with an amine, including monoamines, polyamines (illustrated in the formula above), and hydroxyamines, and a wide variety of linkages between the two moieties is possible besides the simple imide structure shown above, including a variety of amides and quaternary ammonium salts.

The R¹ group in the above structure generally contains an average of at least 8, or 30, or 35 up to 350, or to 200, or to 100 carbon atoms. In one embodiment, the hydrocarbyl group is derived from a polyalkene characterized by an \overline{M}ₙ (number average molecular weight) of at least 500. Generally, the polyalkene is characterized by an \overline{M}ₙ of 500, or 700, or 800, or even 900 up to 5000, or to 2500, or to 2000, or even to 1500 or 1200. Polyolefins which can form the hydrocarbyl substituent can be prepared by polymerizing olefin monomers by well known polymerization methods, as described above, and are also commercially available. The olefin monomers include monoolefins, including monoolefins having 2 to 10 carbon atoms such as ethylene, propylene, 1-butene, isobutylene, and 1-decene. An especially useful monoolefin source is a C₄ refinery stream having a 35 to 75 weight percent butene content and a 30 to 60 weight percent isobutene content. Useful olefin monomers also include diolefins such as isoprene and 1,3-butadiene. Olefin monomers can also include mixtures of two or more monoolefins, of two or more diolefins, or of one or more monoolefins and one or more diolefins. Useful polyolefins include polyisobutylenes having a number average molecular weight of 140 to 5000, in another instance of 400 to 2500, and in a further instance of 140 or 500 to 1500. The polyisobutylene can have a vinylidene double bond content of 5 to 69%, in a second instance of 50 to 69%, and in a third instance of 50 to 95%. The polyolefin can be a homopolymer prepared from a single olefin monomer or a copolymer prepared from a mixture of two or more olefin monomers. Also possible as the hydrocarbyl substituent source are mixtures of two or more homopolymers, two or more copolymers, or one or more homopolymers and one or more copolymers.

The types of amines which may be used include monoamines, polyamines, alkanolamines, thiol-containing amines, and mixtures thereof. In order to be suitably reactive, the amine should contain at least one primary or secondary amine nitrogen atom, unless another reactive moiety, such as an OH group, is also present. The condensation product can be amide or imide, in the case of a monoamine or polyamine or an amide and/or ester and/or heterocyclic reaction product in the case of an alkanolamine.

The amine can be a monoamine having one amine group and includes primary and secondary monoamines such as methylamine and dimethylamine. The monoamine can have 1 to 30 carbon atoms or 2 to 18 or 3 to 12 carbon atoms. Alternatively, the amine can be a polyamine having two or more amine groups where a first amine group is a primary amine group and a second amine group is a primary or secondary amine group. The reaction product of the monocarboxylic acylating agent and the polyamine can contain, in greater or lesser amounts depending on reaction conditions, a heterocyclic reaction product such as 2-imidazoline reaction products. The polyamine can have 2 to 30 carbon atoms. The polyamine can include alkylenediamines, N-alkyl a]-kylenediamines, and polyalkylenepolyamines. Useful polyamines include ethylenediamine, 1,2-diaminopropane, N-methylethylenediamine, N-tallow(C₁₆-C₁₈)-1,3-propylenediamine, N-oleyl-1,3-propylenediamine, polyethylenepolyamines such as diethylenetriamine and triethylenetetramine and tetraethylenepentamine and polyethylenepolyamine bottoms.

The amine can also be an alkanolamine having at least one amine group and at least one hydroxyl group, where the amine group is a primary, secondary or tertiary amine group. The alkanolamine can have 2 to 30 carbon atoms. The alkanolamine can include mono-, di- and trialkoxylates of ammonia such as mono- and di- and triethanolamine, hydroxy-containing monoamines such as a diethoxylated C₁₆ to C₁₈ tallowamine, and hydroxy-containing polyamines such as 2-(2-aminoethylamino)ethanol.

Succinimide dispersants and their methods of preparation are more fully described in U.S. Pat. Nos. 4,234,435 and 3,172,892.

Another class of dispersant is ester-containing dispersants, which are typically high molecular weight esters. These materials are similar to the above-described succinimides except that they may be seen as having been prepared by reaction of a hydrocarbyl acylating agent and a polyhydric aliphatic alcohol such as glycerol, pentaerythritol, or sorbitol. Such materials are described in more detail in U.S. Pat. No. 3,381,022. Similarly, dispersants can be prepared by condensation of a hydrocarbyl acylating agent with both an amine and an alcohol, each as described above.

Mannich dispersants are the reaction product of a hydrocarbyl-substituted phenol, an aldehyde, and an amine or ammonia. The hydrocarbyl substituent of the hydrocarbyl-substituted phenol can have 10 to 400 carbon atoms, in another instance 30 to 180 carbon atoms, and in a further instance 10 or 40 to 110 carbon atoms. This hydrocarbyl substituent can be derived from an olefin or a polyolefin. Useful olefins include alpha-olefins, such as 1-decene, which are commercially available.

The polyolefins which can form the hydrocarbyl substituent can be prepared by polymerizing olefin monomers by well known polymerization methods, and include the polyolefins described above. The hydrocarbyl-substituted phenol can be prepared by alkylating phenol with an olefin or polyolefin described above, such as a polyisobutylene or polypropylene, using well-known alkylation methods.

The aldehyde used to form the Mannich dispersant can have 1 to 10 carbon atoms, and is generally formaldehyde or a reactive equivalent thereof such as formalin or paraformaldehyde.

The amine used to form the Mannich dispersant can be a monoamine or a polyamine, including alkanolamines, having one or more hydroxyl groups, as described in greater detail above. Useful amines include those described above, such as ethanolamine, diethanolamine, methylamine, dimethylamine, ethylenediamine, dimethylaminopropylamine, diethylenetriamine and 2-(2-aminoethylamino)ethanol. The Mannich dispersant can be prepared by reacting a hydrocarbyl-substituted phenol, an aldehyde, and an amine as described in U.S. Pat. No. 5,697,988. In an embodiment of this invention the Mannich reaction product is prepared from an alkylphenol derived from a polyisobutylene, formaldehyde, and an amine that is a primary monoamine, a secondary monoamine, or an alkylenediamine, in particular, ethylenediamine or dimethylamine.

The dispersant can also be a condensation product of a fatty hydrocarbyl monocarboxylic acylating agent, such as a fatty acid, with an amine or ammonia. The hydrocarbyl portion of the fatty hydrocarbyl monocarboxylic acylating agent can be an aliphatic group. The aliphatic group can be linear, branched, or a mixture thereof. The aliphatic group can be saturated, unsaturated, or a mixture thereof. The aliphatic group can have 1 to 50 carbon atoms, in another instance 2 to 30 carbon atoms, and in a further instance 4 to 22 carbon atoms, preferably 8, 10, or 12 to 20 carbon atoms. If the fatty hydrocarbyl monocarboxylic acylating agent is an aliphatic carboxylic acid, it may be seen as comprising a carboxy group (COOH) and an aliphatic group. Thus, the total number of carbon atoms in the carboxylic acid can be 2 to 52, or 3 to 30, or 5 to 23, or 9, 11, or 13 to 21. The monocarboxylic acylating agent can be a monocarboxylic acid or a reactive equivalent thereof, such as an anhydride, an ester, or an acid halide such as stearoyl chloride. Useful monocarboxylic acylating agents are available commercially from numerous suppliers and include tall oil fatty acids, oleic acid, stearic acid and isostearic acid. Fatty acids containing 12 to 24 carbon atoms, including C18 acids, are particularly useful. The amine can be any of the amines described above.

In one embodiment of this condensation product dispersant, the amine is a polyamine. In another embodiment of the invention the monocarboxylic acylating agent and the polyamine are respectively a C₄ to C₂₂ fatty carboxylic acid and an alkylenediamine or a polyalkylenepolyamine, and in a further embodiment the fatty carboxylic acid is isostearic acid and the polyamine is a polyethylenepolyamine such as tetraethylenepentamine.

The monocarboxylic acylating agents and amines are commercially available. Their condensation products can generally be prepared by forming a mixture thereof at ambient to elevated temperatures of 50 to 200° C., and heating the mixture at elevated temperatures of 100 to 300° C. until the reaction product is formed in a satisfactory amount, as is more completely described in the reaction procedures in columns 37 and 39 of U.S. Pat. No. 4,724,091.

Alkyl amino phenol dispersants are hydrocarbyl-substituted aminophenols. The hydrocarbyl substituent of the aminophenol can have 10 to 400 carbon atoms, in another instance 30 to 180 carbon atoms, and in a further instance 10 or 40 to 110 carbon atoms. The hydrocarbyl substituent can be derived from an olefin or a polyolefin, as described above in connection with the Mannich dispersant. The hydrocarbyl-substituted aminophenol can have one or more hydrocarbyl substituents but generally has a single hydrocarbyl substituent. The hydrocarbyl-substituted aminophenol can have one or more amino groups, in another instance can have two amino groups, and in a further instance can have a single amino group. The amino group of the aminophenol can be represented by the formula —NH₂. The hydrocarbyl-substituted aminophenol can be prepared by alkylating phenol with an olefin or a polyolefin, nitrating the alkylated phenol with a nitrating agent such as nitric acid, and reducing the nitrated phenol with a reducing agent such as hydrazine at temperatures of 100 to 200° C. or with a metal catalyzed hydrogenation as described in U.S. Pat. No. 4,724,091.

Hydrocarbyl-amine dispersants are hydrocarbyl-substituted amines. The hydrocarbyl substituent of the amine can be the same as described above. In an embodiment of the invention the hydrocarbyl substituent of the hydrocarbylamine dispersant is a polyisobutylene having a number average molecular weight of 140 to 5600, in a second instance of 420 to 2500, and in a third instance of 140 or 560 to 1540. The amine of component, which is substituted by the hydrocarbyl group, can be derived from ammonia, a monoamine, or a polyamine or alkanolamine as described above. Useful amines include ethylamine, dimethylamine, ethanolamine, ethylenediamine, 2-(2-aminoethylamino)-ethanol, and polyethylenepolyamines such as diethylenetriamine. The hydrocarbyl-substituted amine can be formed by heating a mixture of a chlorinated olefin or polyolefin such as a chlorinated polyisobutylene with an amine such as ethylenediamine in the presence of a base such as sodium carbonate as described in U.S. Pat. No. 5,407,453.

Polyether dispersants include polyetheramines, polyether amides, polyether carbamates, and polyether alcohols. Polyetheramines can be represented by the formula R[OCH₂CH(R¹)]ₙA , where R is a hydrocarbyl group, R¹is hydrogen or a hydrocarbyl group of 1 to 16 carbon atoms, or mixtures thereof, n is 2 to 50, and A can be —OCH₂CH₂CH₂NR²R² or —NR³R³, where each R² is independently hydrogen or hydrocarbyl and each R³ is independently hydrogen, hydrocarbyl, or an alkyleneamine group. Polyetheramines and their methods of preparation are described in greater detail in U.S. Pat. No. 6,458,172, columns 4 and 5. Various Polyetheramides and polyethercarbamates can be prepared by reacting a polyether chain (derived from an alcohol and an alkylene oxide) with a reagent of appropriate functionality. Polyether alcohols include hydrocarbyl-terminated poly(oxyalkylene) monools, including the hydrocarbyl-terminated poly(oxypropylene) monools described in greater detail in U.S. Pat. No. 6,348,075; see in particular column 8. The hydrocarbyl group can be an alkyl or alkyl-substituted aromatic group of 8 to 20 carbon atoms, such as C₁₂₋₁₆ alkyl or nonylphenyl.

Viscosity modifiers containing dispersant functionality. Polymeric viscosity index modifiers (VMs) are extremely well known in the art and most are commercially available. When dispersant functionality is incorporated onto the viscosity modifier, the resulting material is commonly referred to as a dispersant viscosity modifier. For example, a small amount of a nitrogen-containing monomer can be copolymerized with alkyl methacrylates, thereby imparting dispersancy properties into the product. Thus, such a product has the multiple function of viscosity modification and dispersancy, and sometimes also pour point depressancy. Vinyl pyridine, N-vinyl pyrrolidone and N,N′-dimethylaminoethyl methacrylate are examples of nitrogen-containing monomers which can be copolymerized with other monomers such as alkyl methacrylates to provide dispersant viscosity modifiers.

(b) The dimercantothiadiazole. The second component of the present invention is 2,5-dimercapto-1,3-4-thiadiazole or a hydrocarbyl-substituted 2,5-dimercapto-1,3-4-thiadiazole. However, the hydrocarbyl-substituted mercaptothiadizoles of the present invention (as well as the unsubstituted materials) are typically substantially insoluble at 25° C. in nonpolar media such as a hydrocaron oil of lubricating viscosity. Thus, the total number of carbon atoms in the hydrocarbyl-substituents, which tend to promote solubility, will generally be fewer than 8, or 6, or 4. If there are multiple hydrocarbyl substituents, preferably each substituent will contain 4 or fewer carbon atoms.

By the term “substantially insoluble” it is meant that the dimercaptothiadiazole compound will typically dissolve to an extent of less than 0.1 weight percent, preferably less than 0.01 or 0.005 weight percent in oil at room temperature. A suitable hydrocarbon oil of lubricating viscosity in which the solubility may be evaluated is Chevron™ RLOP 100 N oil. The specified amount of the DMTD or substituted DMTD is mixed with the oil and the solubility can be evaluated by observing clarity versus the appearance of residual sediment after, e.g., 1 week of storage.

The mixture of dispersant and the mercaptothiadiazole is treated with either a borating agent or an inorganic phosphorus acid or anhydride, or both the borating agent and the phosphorus compound. The components may be combined and reacted in any order. In particular, the phosphorus acid or borating agent may be a pre-treatment process or a post-treatment process. Thus, for instance, phosphoric acid or boric acid may be reacted with a dispersant in one step, and thereafter the intermediate phosphorylated or borated dispersant may be reacted with the mercaptothiadiazole. Alternatively, the dispersant and mercapthothiadiazole can be first reacted, and then the product treated with phosphoric an inorganic phosphorus acid or a borating agent. In yet another variation, a phosphorylated succinimide dispersant can be prepared by reacting a phosphorus acid with a hydrocarbyl-substituted succinic anhydride to prepare a mixed anhydride-acid precursor, and then reacting the precursor with a polyamine to form a phosphorus-containing dispersant. The phosphorus-containing dispersant can thereafter be reacted with the mercaptothiadiazole and optionally with the borating agent.

Borating agents include various forms of boric acid (including metaboric acid, HBO₂, orthoboric acid, H₃BO₃, and tetraboric acid, H₂B₄O₇), boric oxide, boron trioxide, and alkyl borates of the formula (RO)ₓB(OH)_{y} wherein x is 1 to 3 and y is 0 to 2, the sum of x and y being 3, and where R is an alkyl group containing 1 to 6 carbon atoms. In one embodiment, the boron compound is an alkali or mixed alkali metal and alkaline earth metal borate. These metal borates are generally a hydrated particulate metal borate which are known in the art. Alkali metal borates include mixed alkali and alkaline metal borates. These metal borates are available commercially.

The inorganic phosphorus compound may contain an oxygen atom and/or a sulfur atom as its constituent elements, and is typically a phosphorus acid or anhydride. This component includes the following examples: phosphorous acid, phosphoric acid, hypophosphoric acid, polyphosphoric acid, phosphorus trioxide, phosphorus tetroxide, phosphorous pentoxide (P₂O₅), phosphorotetrathionic acid (H₃PS₄), phosphoromonothionic acid (H₃PO₃S), phosphorodithionic acid (H₃PO₂S₂), phosphorotrithionic acid (H₃PO₂S₃), and P₂S₅. Among these, phosphorous acid and phosphoric acid or their anhydrides are preferred. A salt, such as an amine salt of an inorganic phosphorus compound can also be used. It is also possible to use a plurality of these inorganic phosphorus compounds together. The inorganic phosphorus compound is preferably phosphoric acid or phosphorous acid or their anhydride.

The components are typically reacted by heating the borating agent and/or the inorganic phosphorus compound (together or sequentially) with the remaining components, that is, with the dispersant and the dimercaptothiadiazole, although other orders of reaction are possible, as described above. The heating will be at a sufficient time and temperature to assure solubility of resulting product, typically 80-200° C., or 90-180° C., or 120-170° C., or 150-170° C. The time of reaction is typically at least 0.5 hours, for instance, 1-24 hours, 2-12 hours, 4-10 hours, or 6-8 hours. The length of time required for the reaction is determined in part by the temperature of the reaction, as will be apparent to one skilled in the art. Progress of the reaction is generally evidenced by the evolution of H₂S or water from the reaction mixture. Typically the H₂S is derived from one or more of the sulfur atoms in the dimercaptothiadiazole.

The reaction product can typically contain 0.5 to 2.5 weight percent sulfur derived from component (b), or 1 to 2 weight percent, or 1.25 to 1.5 weight percent sulfur. It can likewise contain 0.2 to 0.6 weight percent boron from component (c), or 0.3 to 1.1 percent phosphorus from component (d), or such amounts from both components (c) and (d).

The reaction can be conducted in a hydrophobic medium such as an oil of lubricating viscosity which may, if desired, be retained in the final product. The oil, however, should preferably be an oil which does not itself react or decompose under conditions of the reaction. Thus, oils containing reactive ester functionality are not generally preferable for use as the diluent. Oils of lubricating viscosity are described in greater detail below.

The relative amounts of the components which are reacted are, expressed as parts by weight prior to reaction are typically 100 parts of (a) the dispersant, per 0.75 to 6 parts of (b) the dimercaptothiadiazole or substituted dimercaptohitadiazole, and 0 to 7.5 parts of (c) the borating agent and 0 to 7.5 parts of (d) the inorganic phosphorus compound, provided that the relative amount of (c)+(d) is at least 0.075 parts. In a preferred embodiment the relative amounts are 100 parts of (a), 1.5 to 3 parts of (b), 0 to 4.5 parts of (c), and 0 to 4.5 parts of (d), provided that (c)+(d) is at least 1.5 parts. In another embodiment, the relative amounts are 100 parts (a): 1.5 to 2.2 parts (b): 3.7 to 4.4 parts (c): 1.5 to 4.4 parts (d). The amounts and ranges of the various components, in particular, (c) and (d), can be independently combined so that there can be, for instance, 3.7 to 4.4 parts of (c) whether or not any of (d) is present, and likewise there can be 1.5 to 4.4 parts (d) whether or not any of (c) is present.

The above-described reaction product is typically used in an oil of lubricating viscosity to provide a lubricant or an additive concentrate. Oils of lubricating viscosity can be derived from a variety of sources, and include natural and synthetic lubricating oils and mixtures thereof. The source of the oil or process for preparing the oil is generally not of particular importance unless that source or process provides some particular benefit, provided that the oil falls within one or more of the descriptions, below.

The natural oils useful in making the inventive lubricants and functional fluids include animal oils and vegetable oils (e.g., lard oil, castor oil) as well as mineral lubricating oils such as liquid petroleum oils and solvent treated or acid-treated mineral lubricating oils of the paraffinic, naphthenic or mixed paraffinic/naphthenic types which may be further refined by hydrocracking and hydrofinishing processes and are dewaxed. Oils of lubricating viscosity derived from coal or shale are also useful. Useful natural base oils may be those designated by the American Petroleum Institute (API) as Group I, II, or III oils. Group I oils contain <90% saturates and/or >0.03% sulfur and have a viscosity index (VI) of ≧80. Group II oils contain ≧90% saturates, ≧0.03% sulfur, and have a VI≧80. Group III oils are similar to group II but have a VI≧120.

Upon occasion, highly refined or hydrocracked natural oils have been referred to as “synthetic” oils. More commonly, however, synthetic lubricating oils are understood to include hydrocarbon oils and halo-substituted hydrocarbon oils such as polymerized and interpolymerized olefins (e.g., polybutylenes, polypropylenes, propylene-isobutylene copolymers, chlorinated polybutylenes); poly(1-hexenes), poly(1-octenes), poly(1-decenes), and mixtures thereof; alkyl-benzenes (e.g., dodecylbenzenes, tetradecylbenzenes, dinonylbenzenes, di-(2-ethylhexyl)-benzenes); polyphenyls (e.g., biphenyls, terphenyls, alkylated polyphenyls); alkylated diphenyl ethers and alkylated diphenyl sulfides and the derivatives, analogs and homologs thereof and the like. Polyalpha olefin oils are also referred to as API Group IV oils. (API Group V oils are “all others.”)

In one embodiment, the oil of lubricating viscosity is a poly-alpha-olefin (PAO). Typically, the poly-alpha-olefins are derived from monomers having from 4 to 30, or from 4 to 20, or from 6 to 16 carbon atoms. Examples of useful PAOs include those derived from 1-decene. These PAOs may have a viscosity from 2 to 150.

Preferred base oils include poly-α-olefins such as oligomers of 1-decene. These synthetic base oils are hydrogenated resulting in an oil of stability against oxidation. The synthetic oils may encompass a single viscosity range or a mixture of high viscosity and low viscosity range oils so long as the mixture results in a viscosity which is consistent with the requirements set forth below. Also included as preferred base oils are highly hydrocracked and dewaxed oils. These petroleum oils are generally refined to give enhanced low temperature viscosity and antioxidation performance. Mixtures of synthetic oils with refined mineral oils may also be employed.

Another class of oils is known as traction oils, which are typically synthetic fluids containing a large fraction of highly branched or cycloaliphatic structures, i.e., cyclohexyl rings. Traction oils or traction fluids are described in detail, for example, in U.S. Pat. Nos. 3,411,369 and 4,704,490.

Other suitable oils can be oils derived from a Fischer-Tropsch process and hydrogenation.

When used as a lubricant, the amount of the above-described reaction product is typically 0.5 to 90 percent by weight of the composition, the balance being the oil of lubricating viscosity and any other components or additives desired for the application at hand. This broad range encompasses both fully formulated lubricant and concentrates. In a fully formulated lubricant the amount of the reaction product is typically 0.5 to 20, 10, or 5 percent by weight, preferably 1 to 4 or 2 to 3 percent by weight. When used as an additive concentrate, (designed to be added to a lubricant to prepare a fully formulated lubricant) the amount of the present reaction product can be 20 to 90 percent by weight or 40 to 80 percent by weight.

Lubricants of the present invention can be used for lubricating a variety of mechanical devices, including internal combustion engines (diesel or gasoline powered, two or four stroke cycle), transmission (including transmissions for automobiles, trucks, and other equipment such as manual transmissions, automatic transmissions, automated manual transmissions, continuously variable transmissions, dual clutch transmissions, farm tractor transmissions, transaxle, heavy duty power-shift transmissions, and wet brakes) as well as gears such as automotive gears and farm tractor gears.

As used herein, the term “hydrocarbyl substituent” or “hydrocarbyl group” is used in its ordinary sense, which is well-known to those skilled in the art. Specifically, it refers to a group having a carbon atom directly attached to the remainder of the molecule and having predominantly hydrocarbon character. Examples of hydrocarbyl groups include:
hydrocarbon substituents, that is, aliphatic (e.g., alkyl or alkenyl), alicyclic (e.g., cycloalkyl, cycloalkenyl) substituents, and aromatic-, aliphatic-, and alicyclic-substituted aromatic substituents, as well as cyclic substituents wherein the ring is completed through another portion of the molecule (e.g., two substituents together form a ring);
substituted hydrocarbon substituents, that is, substituents containing non-hydrocarbon groups which, in the context of this invention, do not alter the predominantly hydrocarbon nature of the substituent (e.g., halo (especially chloro and fluoro), hydroxy, alkoxy, mercapto, alkylmercapto, nitro, nitroso, and sulfoxy);
hetero substituents, that is, substituents which, while having a predominantly hydrocarbon character, in the context of this invention, contain other than carbon in a ring or chain otherwise composed of carbon atoms. Heteroatoms include sulfur, oxygen, nitrogen, and encompass substituents as pyridyl, furyl, thienyl and imidazolyl. In general, no more than two, preferably no more than one, non-hydrocarbon substituent will be present for every ten carbon atoms in the hydrocarbyl group; typically, there will be no non-hydrocarbon substituents in the hydrocarbyl group.

It is known that some of the materials described above may interact in the final formulation, so that the components of the final formulation may be different from those that are initially added. For instance, metal ions (of, e.g., a detergent) can migrate to other acidic sites of other molecules. The products formed thereby, including the products formed upon employing the composition of the present invention in its intended use, may not be susceptible of easy description. Nevertheless, all such modifications and reaction products are included within the scope of the present invention; the present invention encompasses the composition prepared by admixing the components described above.

### EXAMPLES

### Example 1

(DMTD+boric acid): A 12 L, 4-neck round bottom flask fitted with a mechanical stirrer, subsurface nitrogen sparge, thermowell, and Dean-Stark trap fitted with a condenser vented to caustic and bleach traps is charged with 2751.5 g succinimide dispersant (reaction product of polyisobutylene substituted succinic anhydride with polyethylene amine bottoms, containing a total of 1100.6 g diluent oil) and 81.1 g additional diluent oil and is heated, with stirring, to 150° C. To the mixture is added 38.5 g of 2,5-dimercapto-1,3,4-thiadiazole (DMTD) in portions such that each subsequent addition is effected after the previous portion has dissolved. The mixture is stirred at 150° C. until evolution of H₂S ceases. The temperature is then allowed to decrease to 90° C. and 83.1 g boric acid is added, after which the mixture is heated to 150° C. while removing water. When no more water is generated, the mixture is allowed to cool to 130° C. and is filtered through a filter pad packed with filter aid to provide a clear, dark colored product containing 40 percent diluent oil.

### Example 2

(DMTD+boric acid+phosphorous acid): Example 1 is substantially repeated except that the amount of additional diluent oil is 135.8 g, the amount of the DMTD is 38.6 g, the amount of boric acid is 87.2 g, and 77.8 g phosphorous acid is added along with the boric acid. The product contains 40% diluent oil.

### Example 3

(DMTD +boric acid): To a 5 L flask equipped as in Example 1 is charged 2000 g of polyisobutylene-substituted succinic anhydride, including 640 g diluent oil, and the mixture is heated to 150° C. Monopentaerythritol (173.6 g) is added and the temperature is increased to 184° C. over 6 hours and maintained for 11 hours while removing water. Additional diluent oil (486.1g) is added and the temperature is reduced to 160° C., at which time 31 g of polyamine bottoms (equivalent weight about 41) are added dropwise over an hour. The mixture is stirred at temperature for 1 hour, then cooled to 150° C. DMTD (48 g) is added as in Example 1, and the mixture stirred at 150° C. until H₂S evolution ceases. The mixture is cooled to 90° C. and 80 g boric acid is added followed by stirring at 150° C. for an additional 12 hours. Isolation as in Example 1 provides a clear, dark colored product containing 40% diluent oil.

### Example 4

(DMTD +phosphorous acid): To a 5 L flask as in Example 3 is added 2750 g (including 1100 g diluent oil) of a Mannich dispersant (from polyisobutylene-substituted phenol, formaldehyde, and ethylenediamine), along with 77.6 g additional diluent oil. The mixture is heated to 150° C. and DMTD (38.6 g) is added as in Example 1, and stirring continued at temperature until evolution of H₂S ceases. The mixture is cooled to 90° C. and 77.7 g phosphorous acid is added, after which the mixture is heated to 150° C. while removing water. Isolation as in Example 1 provides a clear, dark colored product containing 40% diluent oil.

### Examples 5-11

A lubricant formulation is prepared in Chevron™ RLOP 100 Neutral base oil, containing 9.0 percent by weight polymethacrylate dispersant-viscosity modifier (73.5% chemical, 26.5% diluent oil), 0.78-0.80 percent by weight nonyldiphenylamine-type oxidation inhibitor, 0.30 percent by weight friction modifier condensate of isostearic acid and polyethyleneamines, 0.03 percent by weight of a commercial foam inhibitor, 0.3 percent by weight additional diluent oil, and other components as shown in the Table (each containing the conventional amount of diluent oil, if any). Example 5 is a reference example, in which a conventional succinimide dispersant is employed along with, separately, a borate ester, dibutyl hydrogen phosphite, and phosphoric acid (85%) as conventional additives. In Examples 6 through 10 a multifunctional dispersant, from Examples 1, 2, or 3, is employed, along with other components as indicated. The formulations are adjusted to have, in most cases, approximately the same or comparable amounts of phosphorus and boron by elemental analysis. The resulting lubricants are subjected to a series of conventional wear tests in the Ford Mercon™V specification: A “4-ball” wear test (40 kg force, 120 minutes, 600 r.p.m., lubricated with 100 g of sample), in which scar diameter in mm is reported; the Falex load test, wherein load is applied to V blocks in 110 kg (250 lb.) increments of 1 minute duration until failure of the journal occurs, and load to fail in kg (and lb.) is reported; the FZG test, a modification of ASTM D-5182, 21,700 r.p.m., 150-153° C., 15 minutes at each load stage (up to stage 12) in which maximum load stage is reported, and the Timken Wear screen test, run at 150° C. and 4.1 kg (9 lb.) load for 10 minutes, in which a steel test cup is rotated against a stationary test block, producing sliding contact, reporting wear scar in mm. The results of the testing are shown in the Table.

TABLE

| Ex: | 5* | 6 | 7 | 8 | 9 | 10 | 11 |
|---|---|---|---|---|---|---|---|
| Prod of Ex. 1 | | 4.00 | | | 3.94 | | |
| Prod of Ex. 2 | | | 4.00 | 4.00 | | | |
| Prod of Ex. 3 | | | | | | 4.00 | 4.00 |
| Conventional | 4.00 | | | | | | |
| dispersant | | | | | | | |
| Conventional | 0.44 | | | | | | |
| borate ester | | | | | | | |
| Di-butyl | 0.20 | | | | 0.20 | 0.20 | |
| hydrogen | | | | | | | |
| phosphite | | | | | | | |
| H₃PO₄ (85%) | 0.03 | | | | 0.03 | 0.10 | |
| H₃PO₃ | | 0.11 | | | | | 0.11 |
| Ca sulfonate | | | | | 0.08 | | |
| detergent | | | | | | | |
| Elemental | | | | | | | |
| analysis, %: | | | | | | | |
| B | 0.019 | 0.017 | 0.016 | 0.019 | 0.017 | 0.019 | 0.019 |
| P | 0.038 | 0.042 | 0.039 | 0.038 | 0.034₅ | 0.057 | 0.039 |
| 4-Ball test, | | | | | | | |
| 100° C. | 0.48 | 0.40 | 0.44 | 0.47 | — | 0.48 | 0.48 |
| 150° C. | 0.68 | 0.47 | 0.44 | 0.51 | — | 0.50 | 0.51 |
| Falex test, | | | | | | | |
| 100° C. | 660 | 680 | 570 | 570 | — | 520 | — |
| | (1450) | (1500) | (1250) | (1250) | | (1150) | |
| 150° C. | 140 | 1590 | 570 | 570 | — | 450 | — |
| | (300) | (3500) | (1250) | (1250) | | (1000) | |
| FZGTest | 10 | 12 | 12 | — | — | 12 | 12 |
| (pass stage) | | | | | | | |
| Timken | 0.661 | 0.923 | 0.710 | 0.860 | — | 0.609 | 1.315 |
| screen test | | | | | | | |

*Reference example
—Test not run

The results in the Table show that the wear performance of samples containing the compositions of the present invention is improved, as evidenced by reduced wear scar diameter (especially at higher temperatures), and as evidenced by increased load (again, particularly at higher temperatures). The copper corrosion rating (ASTM D-130, 3 hours, 149° C.) for Example 5 is 1-A; for Examples 6 through 11 it is 1-B through 2-C; corrosion can be reduced by conventional means.

Each of the documents referred to above is incorporated herein by reference. Except in the Examples, or where otherwise explicitly indicated, all numerical quantities in this description specifying amounts of materials, reaction conditions, molecular weights, number of carbon atoms, and the like, are to be understood as modified by the word “about.” Unless otherwise indicated, each chemical or composition referred to herein should be interpreted as being a commercial grade material which may contain the isomers, by-products, derivatives, and other such materials which are normally understood to be present in the commercial grade. However, the amount of each chemical component is presented exclusive of any solvent or diluent oil, which may be customarily present in the commercial material, unless otherwise indicated. It is to be understood that the upper and lower amount, range, and ratio limits set forth herein may be independently combined. Similarly, the ranges and amounts for each element of the invention can be used together with ranges or amounts for any of the other elements. As used herein, the expression “consisting essentially of” permits the inclusion of substances that do not materially affect the basic and novel characteristics of the composition under consideration.

1. A composition comprising the product prepared by heating together:
(a) a dispersant and
(b) 2,5-dimercapto-1,3,4-thiadiazole or a hydrocarbyl-substituted 2,5-di-mercapto-1,3,4-thiadiazole which is substantially insoluble in a hydrocarbon oil of lubricating viscosity at 25° C., and further either
(c) a borating agent or
(d) an inorganic phosphorus compound, or both (c) and (d), said heating being sufficient to provide a reaction product of (a), (b), and (c) or
(d) which is soluble in said hydrocarbon oil at 25° C.

2. The composition of claim 1 wherein the dispersant is a succinimide dispersant.

3. The composition of claim 1 wherein the dispersant is a Mannich dispersant.

4. The composition of claim 1 wherein the dispersant an ester-containing dispersant.

5. The composition of claim 1 wherein the dispersant is a viscosity modifier containing dispersant functionality.

6. The composition of claim 1 wherein component (b) is 2,5-dimercapto-1,3,4-thiadizole.

7. The composition of claim 1 wherein component (b) is a hydrocarbyl-substituted 2,5-dimercapto-1,3,4-thiadizole wherein the hydrocarbyl group or groups contain a total of less than about 8 carbon atoms.

8. The composition of claim 1 wherein the borating agent is an inorganic borating agent.

9. The composition of claim 1 wherein the borating agent is boric acid.

10. The composition of claim 1 wherein the inorganic phosphorus compound is phosphoric acid, phosphorous acid or an anhydride thereof.

11. The composition of claim 1 wherein both the borating agent and the inorganic phosphorus acid or anhydride have been heated with the remaining components.

12. The composition of claim 1 wherein the components have been heated together at about 80 to about 200° C. for at least about 0.5 hours.

13. The composition of claim 1 wherein the components have reacted as evidenced by the evolution of H₂S or H₂O.

14. The composition of claim 1 wherein the components are heated together in a hydrophobic medium.

15. The composition of claim 14 wherein the hydrophobic medium is an oil of lubricating viscosity.

16. The composition of claim 15 wherein the oil of lubricating viscosity is retained in the composition of matter.

17. The composition of claim 1 wherein the relative amounts, by weight, of components (a), (b), (c), and (d), prior to heating, are about 100 of (a): (0.75 to 6 of (b)): (0 to 7.5 of (c)): (0 to 7.5 of (d)), provided that the relative amount of (c)+(d) combined is at least about 0.075.

18. The composition of claim 1 wherein the relative amounts, by weight, of components (a), (b), (c), and (d), prior to heating, are about 100 of (a): (1.5 to 3 of (b)): (0 to 4.5 of (c)): (0 to 4.5 of (d)), provided that the relative amount of (c)+(d) combined is at least about 1.5.

19. The composition of claim 1 wherein the composition comprises about 0.5 to about 2.5 percent by weight S derived from component (b) and either about 0.2 to about 0.6 percent by weight B from component (c), or about 0.3 to about 1.1 percent by weight P from component (d), or said amounts from both components (c) and (d), on an oil free basis.

20. A composition comprising an oil of lubricating viscosity and the reaction product of claim 1.

21. The composition of claim 20 wherein the amount of the reaction product is about 0.5 to about 90 percent by weight of the composition.

22. The composition of claim 21 wherein the amount of the composition within the oil-containing composition is about 0.5 to about 5 percent by weight.

23. The composition of claim 21 wherein the amount of the composition within the oil-containing composition is about 20 to about 90 percent by weight.

24. A method for lubricating a mechanical device, comprising supplying thereto the composition of claim 20.

25. The method of claim 24 wherein the mechanical device is an internal combustion engine.

26. The method of claim 24 wherein the mechanical device is an automatic transmission.
